(19) United States
(12) Patent Application Publication
(10) Pub. No.: US 2015/0264789 A1
(43) Pub. Date: Sep. 17, 2015

(54) METHODS AND SYSTEMS FOR CONTROLLING VOLTAGE SWITCHING

(71) Applicant: General Electric Company, Schenectady, NY (US)

(72) Inventors: Antonio Caiafa, Niskayuna, NY (US); Dominique Poincloux, Paris (FR); Marcos Garcia Arregui, Paris (FR)

(73) Assignee: General Electric Company, Schenectady, NY (US)

(21) Appl. No.: 14/211,894

(22) Filed: Mar. 14, 2014

(51) Int. Cl. H05G 1/32; H03K 17/56

(52) U.S. Cl. CPC H05G 1/32; H03K 17/56

(57) ABSTRACT

Methods and systems for controlling voltage switching are provided. One system includes a transformer having primary and second windings, and a plurality of switching devices, wherein at least two of the switching devices are configured to produce different voltage outputs from a voltage input generated at the transformer. The plurality of switches are electrically referenced to one or more voltages. The system also includes a drive arrangement connected to the plurality of switches and configured to receive one or more voltage control pulses through the primary windings of the transformer, wherein the drive arrangement switches one or more of the plurality of switches based on the one or more voltage control pulses.

### BACKGROUND

Electrical devices (e.g., x-ray tubes for computed tomography (CT) x-ray imaging systems) may use active switches to control the switching of the power source or supply for the devices (e.g., power source or supply for the x-ray tubes). For example, active switches are typically controlled by driving circuits using lower voltage signals, which may be implemented without much complexity when the switches are electrically referenced to ground. However, as the switches are electrically referenced to higher and higher voltages, more complex and bulky driving circuits are needed to allow the switches to turn on and off independent of each other. In these systems, particularly when the switches are referenced to different higher voltages, the control of the multiple switches includes switching equipment that is more complex and bulky (e.g., a large amount of fiber optics for communicating control signals), adding size, complexity and cost to the overall system.

Known systems for controlling voltage switching, such as for controlling the voltage switching to an x-ray tube (e.g., fast kV switching for dual x-ray systems), may include isolated gate drives. These drives control the voltage switching to control the energy of the electron beam generated by the x-ray source, such as by controlling the voltage to the electron emission source and target of the x-ray tube. For example, CT imaging systems may comprise energy-discriminating (ED), multi-energy (ME), and/or dual-energy (DECT) imaging systems that may be referred to as an EDCT, MECT, and/or DECT imaging system. The EDCT, MECT, and/or DECT imaging systems are configured to measure energy-sensitive projection data. The energy-sensitive projection data may be acquired using multiple applied x-ray spectra by modifying the operating voltage of the x-ray tube or utilizing x-ray beam filtering techniques (e.g., energy-sensitive x-ray generation techniques), or by energy-sensitive data acquisition by the detector using energy-discriminating, or with photon counting detectors or dual-layered detectors (e.g., energy-sensitive x-ray detection techniques).

For example, with x-ray generation techniques, various system configurations utilize modification of the operating voltage of the x-ray tube including: (1) acquisition of different energy (e.g., low-energy and high-energy) projection data from two sequential scans of the object using different operating voltages of the x-ray tube, (2) acquisition of projection data utilizing rapid or fast switching of the operating voltage of the x-ray tube to acquire low-energy and high-energy information for an alternating subset of projection views, or (3) concurrent acquisition of energy-sensitive information using multiple imaging systems with different operating voltages of the x-ray tube.

The known drive controls for these systems may be referenced to high voltages. However, when referenced to the high voltages, the conventional hardware to control the switching is physically large, thereby adding size, weight, and/or cost to the system. In some systems, the lack of space in the overall system may prevent implementation of these drive controls.

### BRIEF DESCRIPTION

In accordance with various embodiments, a voltage switching system is provided that includes one or more transformers having a plurality of primary and secondary windings, and a plurality of switching devices, wherein at least two of the switching devices are configured to produce different voltage outputs from a voltage input generated at the transformer. The plurality of switches is electrically referenced to one or more voltages. The voltage switching system also includes a drive arrangement connected to the plurality of switches and configured to receive one or more voltage control pulses through the primary windings of the transformer, wherein the drive arrangement switches one or more of the plurality of switches based on the one or more voltage control pulses.

In accordance with other various embodiments, an x-ray system is provided that includes an x-ray source including an x-ray tube configured to operate at a plurality of different voltages and a plurality of switching devices, wherein at least two of the switching devices are configured to produce different voltage outputs from a voltage input generated at a transformer to control the switching of the x-ray tube at the plurality of different voltages. The x-ray system also includes a drive arrangement connected to the plurality of switches and configured to receive one or more voltage control pulses through the primary windings of the transformer(s), wherein the drive arrangement switches one or more of the plurality of switches based on the one or more voltage control pulses.

In accordance with yet other various embodiments, a method for controlling voltage switching is provided that includes configuring a voltage switching system as described above.

### BRIEF DESCRIPTION OF THE DRAWINGS

FIG. 1 is a simplified block diagram of a power system in accordance with various embodiments.

FIG. 2 is schematic diagram of a switching drive arrangement in accordance with one embodiment.

FIG. 3 is a schematic diagram of a switching architecture including the switching drive arrangement of FIG. 2.

FIG. 4 is a schematic diagram of another switching architecture including the switching drive arrangement of FIG. 2.

FIG. 5 is a schematic diagram of another switching architecture including the switching drive arrangement of FIG. 2.

FIG. 6 is schematic diagram of a switching drive arrangement in accordance with another embodiment.

FIG. 7 is schematic diagram of a switching drive arrangement in accordance with another embodiment.

FIG. 8 is schematic diagram of a switching drive arrangement in accordance with another embodiment.

FIG. 9 is a diagram of a voltage waveform in accordance with an embodiment.

FIG. 10 is a diagram illustrating transformers in accordance with various embodiments.

FIG. 11 is a flowchart of a method for controlling voltage switching in accordance with various embodiments.

FIG. 12 is a pictorial view a computed tomography (CT) imaging system in connection with which various embodiments may be implemented.

FIG. 13 is a block schematic diagram of the CT imaging system of FIG. 8.

FIG. 14 is a schematic block diagram of an x-ray imaging system in connection with which various embodiments may be implemented.

### DETAILED DESCRIPTION

The following detailed description of certain embodiments will be better understood when read in conjunction with the appended drawings. As used herein, an element or step recited in the singular and proceeded with the word “a” or “an” should be understood as not excluding plural of said elements or steps, unless such exclusion is explicitly stated. Furthermore, references to “one embodiment” are not intended to be interpreted as excluding the existence of additional embodiments that also incorporate the recited features. Moreover, unless explicitly stated to the contrary, embodiments “comprising” or “having” an element or a plurality of elements having a particular property may include additional elements not having that property.

Although the various embodiments may be described herein within a particular operating environment, for example a particular imaging system, such as a “third generation” computed tomography (CT) system (e.g., a sixty-four-slice CT system), it should be appreciated that one or more embodiments are equally applicable for use with other configurations and systems, such as for different types of medical and baggage scanning systems. For example, various embodiments are applicable to x-ray radiographic imaging systems as well as x-ray tomosynthesis imaging systems. Additionally, embodiments will be described with respect to the detection and conversion of x-rays. However, it also should be appreciated that embodiments are equally applicable for the detection and conversion of other high frequency electromagnetic energy. Also, although the x-ray tube and detector may be described to rotate around the object being imaged, alternate configurations wherein the detector and x-ray source are held stationary and the object is rotated are also contemplated, such as is used for industrial non-destructive testing purposes. Hence, although discussed in the context of CT systems, the various embodiments may be applied to projection x-ray imaging used in other medical and industrial radiographic applications as well.

Various embodiments provide systems and methods for controlling voltage switching, which may include a gate drive for controlling multiple devices floating at multiple voltages. For example, some embodiments provide control of switches simultaneously or concurrently when the switches are referenced to high voltages (e.g., 10 kV-300 kV), including when referenced to multiple high voltages. By practicing one or more embodiments, control of switches for voltages applied or referenced to multiple devices may be simplified, including having controls with less components and being less complex. For example, various embodiments may be used for super-fast kV switching applications, such as for use in dual x-ray systems. By practicing one or more various embodiments, fast switching between a first voltage level and a second voltage level (e.g., high and low voltage levels) may be achieved, enabling improved separation in the mean energy of applied x-ray spectra, thereby improving material decomposition and effective atomic number estimation of a scanned object.

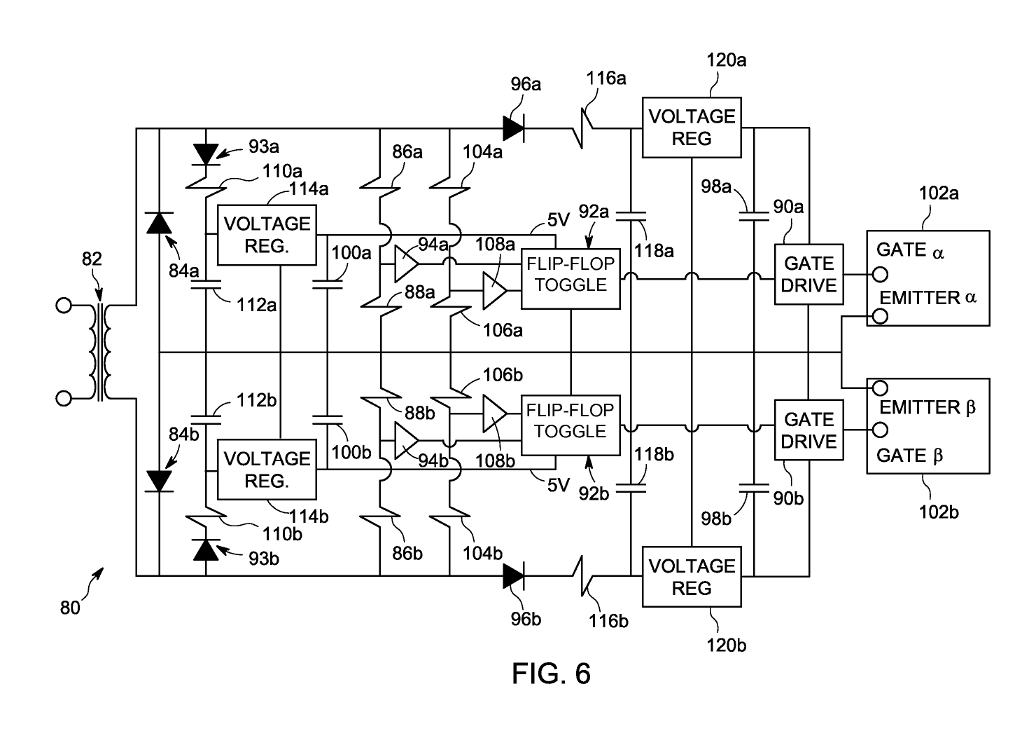

By practicing one or more embodiments, for example as shown in FIG. 2, a plurality of switches (e.g., two switches) may be independently controlled with a single transformer winding. By practicing one or more embodiments, for example as shown in FIG. 6, drive power may be provided, as well as control signals, with a single transformer. Thus, in various embodiments, one or more controls or functions may be performed using a single component, such as a single transformer or transformer winding. Accordingly, a reduced number of transformers or other control devices may be used in various embodiments. Additionally, a reduced cost or size of the transformers may be provided in some embodiments. For example, in high voltage circuits, the cost and size of the transformers is primarily due to the high voltage insulation used, which can be reduced by practicing one or more embodiments.

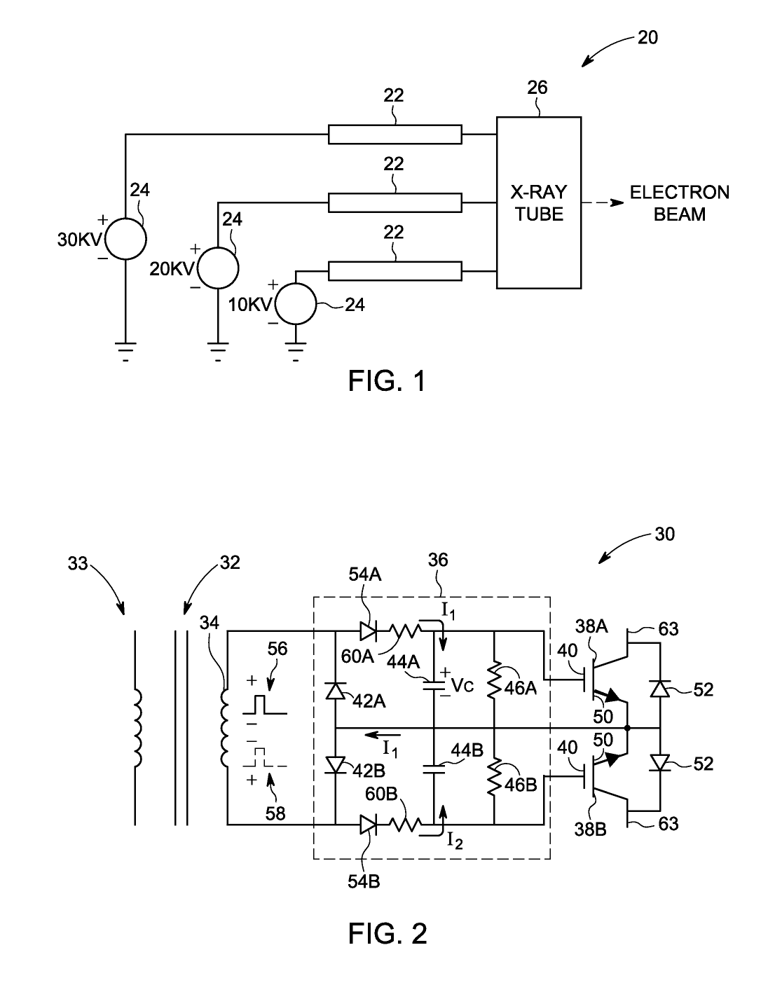

Various embodiments may be implemented in systems where the voltage to be switched is very large (e.g., 200 kV or greater), the parasitic capacitances to ground are also very large, or the energy required by the load is relatively small, as is the case for industrial inspection systems utilizing stationary anode x-ray tube technology. In various embodiments, power or voltage switching of multiple devices or components referenced to different high voltages is provided. For example, as shown in FIG. 1 illustrating a power system 20, a plurality of devices, illustrated as printed circuit boards (PCBs) 22 are each powered or referenced to multiple voltages, illustrated as a plurality power sources 24. For example, in the illustrated embodiment, three PCBs 22 are referenced to three different power sources 24, in particular, referenced to multiple high voltages (in this embodiment, 10 kV, 20 kV and 30 kV). It should be noted that in various embodiments, at least two of the referenced voltages are different.

In one embodiment, the PCBs 22 may be power supply or power control boards for controlling the power to an x-ray tube 26 to control the energy of the electron beam, such as in a fast switching architecture. However, it should be noted that various embodiments may be implemented in connection with different types of systems that have different referenced voltage levels. Additionally, the power switching to additional devices or components may be controlled and the three components in FIG. 1 are merely for illustration. For example, in some embodiments, 50, 60, or more components may be controlled.

In various embodiments, different gate drive arrangements may be provide for controlling the switching of the different referenced voltages. For example, passive and/or active switching drive arrangements may be provided. In particular, FIG. 2 illustrates a passive drive arrangement 30 in accordance with various embodiments. In this embodiment, the gate drive is powered by the received signal itself as described in more detail herein.

The passive drive arrangement 30 may be used to control switching of power from a transformer 32 having a primary winding 33 and a secondary winding 34. The passive drive arrangement 30 includes a gate drive circuit 36 that controls the power to a pair of switching devices 38, illustrated as Insulated Gate Bipolar Transistor (IGBT). However, it should be appreciated that different switching devices may be used, for example metal-oxide-semiconductor field-effect transistors (MOSFETs), or different types of transistors. Additionally, it should be noted that the switching devices may be formed using silicon (Si), Silicon Carbide (SiC), Gallium Nitride (GaN) or any other material suitable to build controllable solid state devices. In various embodiments, the gate drive circuit 36 controls the drive signal to the gates 40 of the switching devices 38.

In particular, the gate drive circuit 38 includes a pair of diodes 42 connected, through a pair of diodes 54 in series with a resistor 60, with a pair of capacitors 44, which are connected in parallel with a pair of resistors 46. This parallel connection arrangement is illustrated as connected across the secondary winding 34 of the transformer 32. Each set of components, namely the set of the diode 42a and the diode 54a, resistor 60a, capacitor 44a and resistor 46a and the set of the diode 42b and the diode 54b, capacitor 44b and resistor 46b are connected across the gate 40 and source 50 of each of the switching devices 38. A pair of diodes 52 is also connected between the source 50 and drain 63 of each of the switching devices 38 to complete the power arrangement. It should be noted that in some embodiments, the switching devices 38 may be connected, for example, in a common emitter configuration (as shown in FIG. 2). It also should be noted that the diodes 42 and the diodes 52 in each of these pairs is connected in opposing directions, illustrated as having anodes thereof connected to each other.

The gate drive circuit 36 also includes a pair of diodes 54 connected in series with the resistor 60, and between the diodes 42 and capacitors 44. In particular, the cathode of the diodes 42a and 42b are connected to the anodes of the diodes 54a and 54b, respectively. The resistors 60 operate as a filtering element. It should be noted that in some embodiments the resistors 60 are not provided, in which case the pair of diodes 54 are directly connected between the diodes 42 and the capacitors 44.

In operation, and for example, a positive pulse voltage 56 may be sent from the transformer 32, by means of the primary winding 33, in one direction. However, as described herein different voltage control pulses or signals may be used. With the illustrated pulse voltage 56, a current I₁ is generated (through the diodes 54a and 42b, and the resistor 60a if provided) that charges the capacitor 44a to a voltage (Vc), which may be referred to as a charged state, while the current is blocked from charging the capacitor 44b. The charging of the capacitor 44a results in a drive signal at the gate 40 of the switching device 38a, which turns on the switching device 38a when the voltage charge of the capacitor 44a exceeds the threshold voltage of the gate 38a, allowing current flow through the switching device 38a. The switching device 38a may be maintained in an on state by sending a train of pulses to maintain the charge of the capacitor 44a. Once a train of pulses is stopped, the capacitor 44a discharges through the resistor 46a, which may be referred to as a discharged state. As the capacitor 44a discharges, when the voltage charge of the capacitor 44a falls below the threshold voltage of the gate 40, the switching device 38a turns off, blocking current flow therethrough.

In operation, a negative pulse voltage 58 may be sent from the transformer 32 in one direction. In this case, the switching of the switching device 38b is controlled. In particular, with the illustrated pulse voltage 58, a current I₂ is generated (through the diodes 54b and 42a, and the resistor 60b if provided) that charges the capacitor 44b, while the current is blocked from charging the capacitor 44a. The charging of the capacitor 44b results in a drive signal at the gate 40 of the switching device 38b, which turns on the switching device 38b when the voltage charge of the capacitor 44a exceeds the threshold voltage of the gate 38b, allowing current flow through the switching device 38b. The switching device 38b may be maintained in an on state by sending a train of pulses to maintain the charge of the capacitor 44b. Once a train of pulses is stopped, the capacitor 44b discharges through the resistor 46b. As the capacitor 44b discharges, when the voltage charge of the capacitor 44b falls below the threshold voltage of the gate 40, the switching device 38b turns off, blocking current flow therethrough.

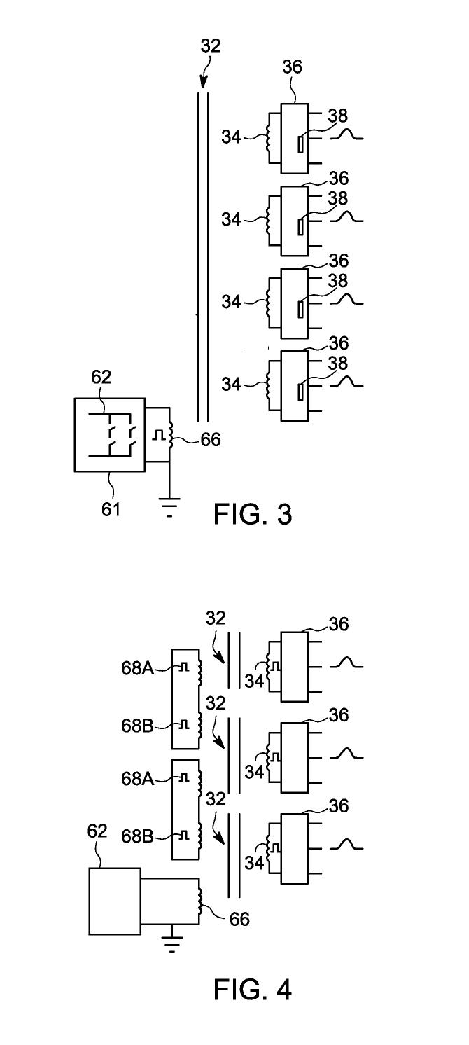

As illustrated in FIG. 3, a plurality of gate drive circuits 36 may be provided and connected to a plurality of secondary windings 34 of a transformer 32. The primary winding 66 of the transformer 32 connected to a single power control, illustrated as a voltage tank 61 having switches to control the generation of positive of negative pulse voltages as described above. As can be seen, using multiple secondary windings 34 (also referred to as secondaries) that may be floating at different voltages, a plurality of gate drive circuits 36 may be controlled using a single signal (applied to the primary winding 66) generated from the voltage tank 61. It should be noted that even if the reference voltage changes, it does not have an effect as the secondary windings 34, and therefore the gate drive circuits 36, are isolated. Thus, the switching devices 38 may be turned on and maintained on without any external or additional power.

Variations and modifications are contemplated. For example, as illustrated in FIG. 4, one transformer 32 may be provided for each gate drive circuit 36, for example, for each PCB 22 (shown in FIG. 1). In this embodiment, the voltage signal is reproduced, with each being sent to a different gate drive circuit 36. It should be noted that in this embodiment, the isolation for each of the gate drive circuits 36 is reduced as a result of use of the multiple transformers 32. Thus, in this embodiment, there is one transformer 32 per PCB board driving multiple gate drive circuits 36.

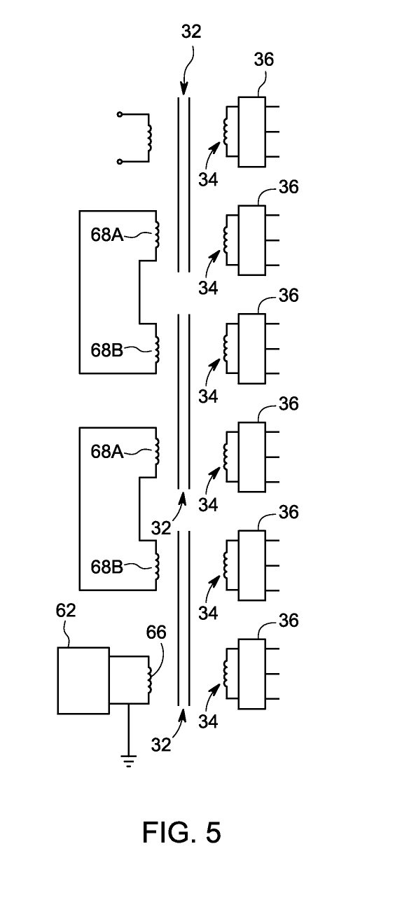

However, in other embodiments, there may be multiple secondary windings 34 per transformer 32 such that the plurality of gate signals are generated by a plurality of transformers 32 and a plurality of circuits 36 per transformer, as shown in FIG. 5. For example, each of the transformers 32 has two primaries (primary windings), primary winding 68a (and primary winding 66 for the first transformer illustrated at the bottom of FIG. 5) to receive the signal from the previous transformer (or the circuit 62 for the first transformer) and one primary winding 68b to send the signal to the next transformer 32. Additionally, each of the transformers 32 includes two windings 34 on the secondary side to send the voltage pulses to each of the gate drive circuits 36. It should be noted that the numbers of secondaries is not limited to two. Additionally, it should be noted that an arrangement with multiple transformers 32 allows for a much smaller size when the X-ray generator produces a very large voltage.

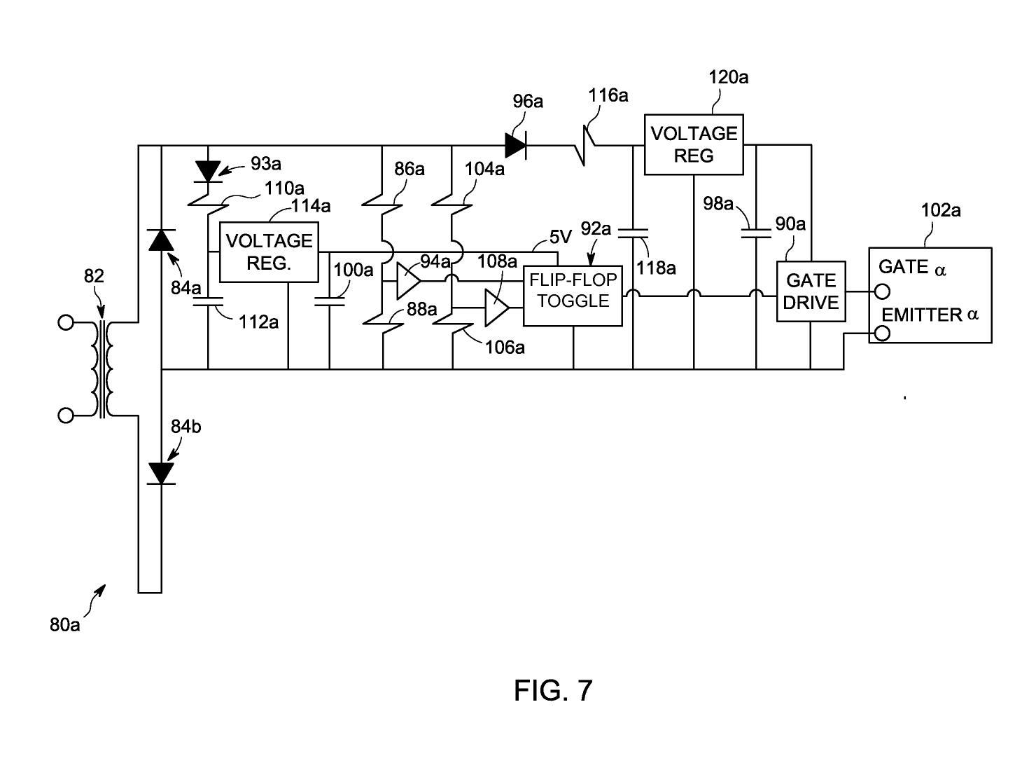

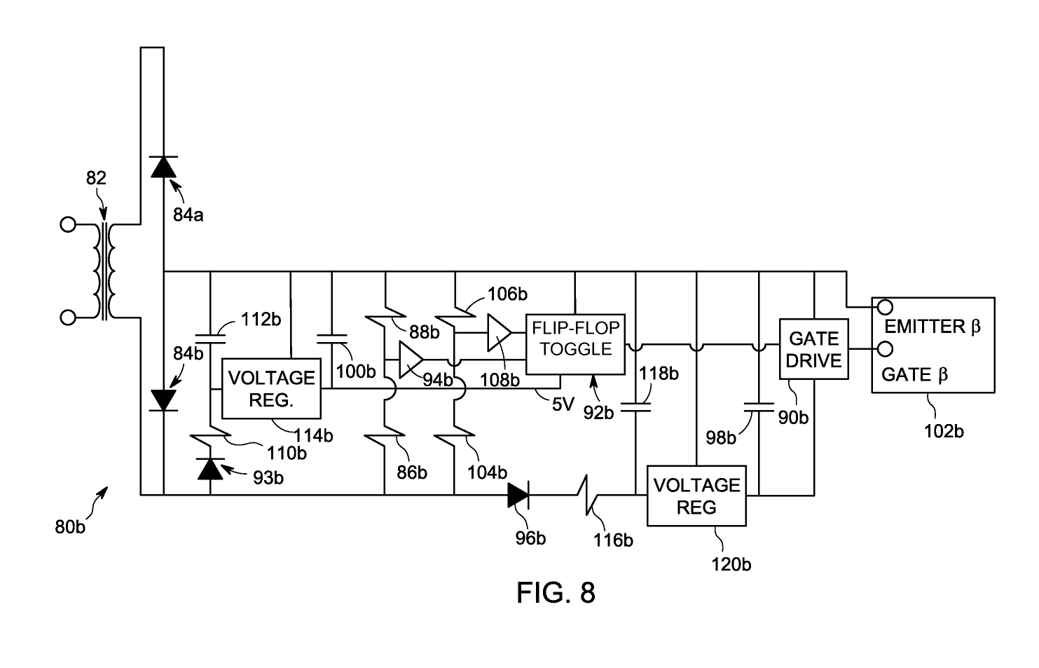

Other embodiments may provide an active drive arrangement 80, for example, as shown in FIGS. 6 through 8. In the embodiment shown in FIG. 6, a pair of gate drive devices 90a and 90b are controlled by signals from a transformer 82 using a pair of flip-flops 92a and 92b operating in a toggle mode. It should be noted that although the active drive arrangement is shown controlling a pair of gate drive devices 90a and 90b, each gate drive device 90a and 90b may be separately controlled by a corresponding transformer 82, such that the top and bottom portions of the circuit shown in FIG. 6 are separated (i.e., not in a common emitter configuration). These alternative arrangements are shown in FIGS. 7 and 8.

The active drive arrangement 80 includes a pair of diodes 84 each connected in parallel with a pair of resistors 86 and 88. It should be noted that each separate elements of the pair is generally designated as “a” and “b”, for example, diodes 84a and 84b. The pair of resistors 86 and 88 form a resistive voltage divider with a buffer 94 connected therebetween. The output of the buffer 94 is connected to the clock pin of the flip-flop 92 and the output (illustrated as the q output) of the flip-flop 92 is connected to the gate drive device 90. Similarly, the diodes 84 are each connected in parallel with another pair of resistors 104 and 106. The pair of resistors 104 and 106 forms another resistive divider with another buffer 108 connected therebetween. The output of the buffer 108 is connected to the RESET pin of the flip flop 92. The series of the diode 93, resistor 110, and capacitor 112 are connected in parallel with the diode 84.

Further, the input of the voltage regulator 114 is connected in parallel with the capacitor 112 and the output is connected in parallel with the capacitor 100 and the 5V reference voltage (although other reference voltages may be used) of the flip-flop 92. Similarly, the series connection of the diode 96, the resistor 116, and the capacitor 118 are connected in parallel with the diode 84. The input of the 15V voltage regulator 120 (although other voltage inputs may be used) is connected in parallel with the capacitor 118 and the output is connected in parallel with the other capacitor 98 and the 15V reference voltage of the gate drive 90. Additionally the output of the gate drive device 90 and the switching devices 102 are connected in a common emitter configuration.

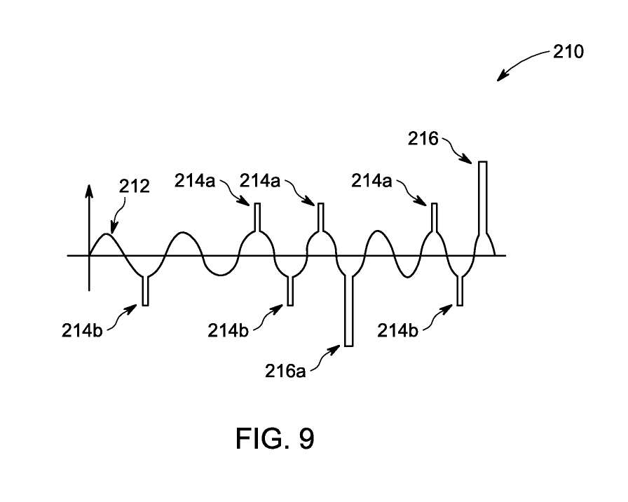

In operation, a voltage waveform 210 such as shown in FIG. 9 may be applied to the input terminals of the transformer 82. The voltage waveform 210 in some embodiments is formed by three components. However, it should be appreciated that voltage waveform 210 is merely for example and different waveforms having different components may be used. One component 212 provides power to the gate drive and the logic component such as the flip-flop 92 and has relatively small amplitude (e.g., 16V). The second component 214 (referred to as pulses) provides the signal for the clock of the flip-flop 92 and has an amplitude larger than the first component (e.g., 20V), and is limited in duration. The third component 216 has the largest amplitude (e.g., 24V) and is used to reset the flip-flop 92 when needed (referred to as large pulses). It should be noted that the positive portion of the waveform 210 provides power and signals to the components connected in parallel with the diode 84a, and the negative portion provides power and signals to the components connected in parallel with the diode 84b. For example, the polarity of the voltage signal may be used to control the switching on and off of the switching devices 102 using the flip-flops 92 as described in more detail below. However, in this embodiment, the switching device 102a or 102b may be maintained on or switches off by sending different numbers or types of pulses as part of a waveform 210. It should be noted that in FIG. 9, the positive components labeled with an “a” (such as 214a and 216a) control the “a” portion of FIG. 6 (upper portion) and FIG. 7, and the negative components labeled with a “b” (such as 241b and 214b) control the “b” of portion FIG. 6 (bottom portion) and FIG. 8.

As can be seen, the waveform 210 defines a pulse train having lower amplitude components 212, medium amplitude components (pulses) 214, namely pulses having a higher amplitude than components 212, and larger amplitude pulses 216, namely having higher amplitude than the pulses 214. In the illustrated embodiment, the waveform 210 defines signals that are used to send the power for powering flip flop 92 and the gate drive 90, the pulses 214 are used to switch the flip-flops 92, and the pulses 216 are used to reset the flip flop 92, resulting in control signals being output that cause the switching device 102a or 102b to turn on or off (e.g., because the signal is sent to the clock, In operation, for example, an even or odd number of higher pulses 214, for example, 2 or 1, may be used to turn on and off the switching devices 102). It should be noted that in various embodiments, the even higher amplitude pulse 216 (e.g., higher amplitude than 212 and 214) may be sent, which resets the flip-flops 92 to a known state (at a voltage level to drive the reset (r) input of the flip-flop 92). Thus, for example, with a JK flip-flop operating in a toggle mode, the switching devices 102 may be turned on and off by the number of pulses sent through the primary of the transformer 82. Also, if the signal frequency is too low, the capacitors 100 may be recharged by a pulse smaller in amplitude, namely the pulses 212, without triggering the signal circuitry. It should be noted that the power can be sent with the signal.

In the illustrated embodiment, the power (e.g., +5V) is sent through the transformer 82, rectified and filtered by the diode 93, the resistor 110 and the capacitor 112, then regulated to 5V constant by the voltage regulator 114 and the capacitance of the capacitor 100. Similarly, the power for the gate drive (e.g. 15V) is sent through the transformer 82, rectified and filtered by the diode 96, the resistor 116, and the capacitor 118, then regulated to 15V constant by the voltage regulator 120 and the capacitance 98. It should be noted that the complementary q output of the flip-flops 92 may be used to control an additional switch that is referenced to the same voltage level of the main switches (switching devices 102), but is complementary thereto.

Moreover, in this embodiment, the controlling signals are also sent through the transformer 82. The voltage regulators 114 and 120 will not be affected by the controlling pulses 214 or 216 because of the pulses short duration and the filtering action of the resistor 110 and capacitor 112, and the resistor 116 and the capacitor 118 respectively. The resistive divider formed by the resistors 86 and 88 is sized such that the pulse appearing at the input of the buffer 94 is large enough to be changed into “logic 1” only if the magnitude of the pulse 214 exceeds a certain threshold voltage. The resistive divider formed by resistor 104 and resistor 106 is sized such that a pulse 214 that is large enough to be changed into “logic 1” by the buffer 94 is not large enough to be changed into “logic 1” by the buffer 108. Accordingly, only pulses such as 216 will be changed into “logic 1” by the buffer 108 and reset the flip-flop 92. It should be noted that if a pulse is large enough to reset the flip-flop 92, that same pulse creates a clock signal as well, which is not an issue since the reset command overrides all other commands including the signal on the clock. Additionally, it should be noted that the logic inputs to the flip-flop 92 will be protected by over-voltages by voltage limiters (not shown).

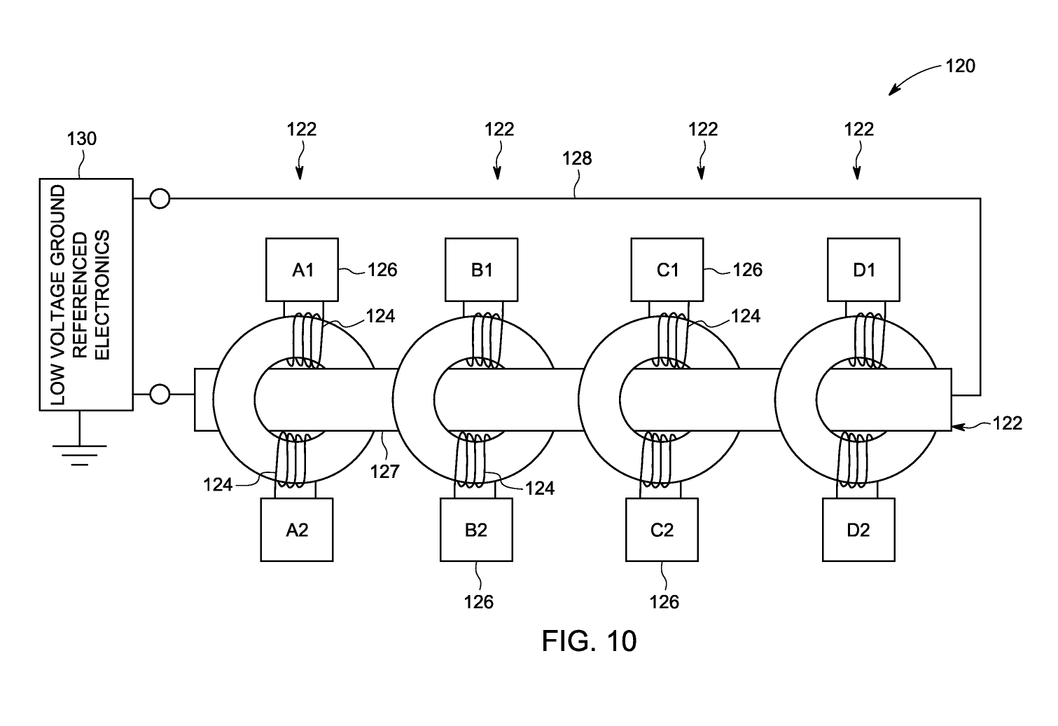

The voltage switching control of various embodiments, thus, may be implemented as generally illustrated in FIG. 10. For example, the switching control may be implemented with transformers 120 (operating as a high voltage generator) with a primary winding 122 on each side. The transformer 120 includes a plurality of secondary windings 124 connected with each of the primary windings 122 and with a drive arrangement 126, which may be the passive drive arrangement 30 or active drive arrangement 80. The illustrated embodiment shows eight secondary windings 124: four toroids with two windings each, connected with each of the primary windings 122. However, additional toroids or windings per toroid may be provided. Additionally, although the primary windings 122 (also referred to as the primaries) of the transformers 120 are connected in series, a parallel, or cascaded connection of the primary side of the isolation transformers 120 may be provided.

It should be noted that in the illustrated embodiment, the section 127 of the primary windings 122 is insulated, while the section 128 of the primary windings 122 may be not insulated. It also should be noted that additional transformers may be provided, for example, up to forty or more. The primary windings 122 are also connected to low voltage ground referenced electronics 130 to generate the voltage pulses as described herein.

It further should be noted that the drive arrangements 126 connected with the secondary windings 124 are used to control voltage switching as described in more detail herein. It additionally should also be noted that the drive arrangements may include protection elements as desired or needed.

In operation, various embodiments allow control of two or more sets of devices that can be at the same voltage reference and/or different voltage references. The voltage references (as well as the number and value of each) may be varied as desired or needed, as well as the values of the component parts of the various embodiments. It should be noted that the various embodiments can control two or more sets of devices independently, as well as at two or more different frequencies, although the frequencies are integer multiples of each other.

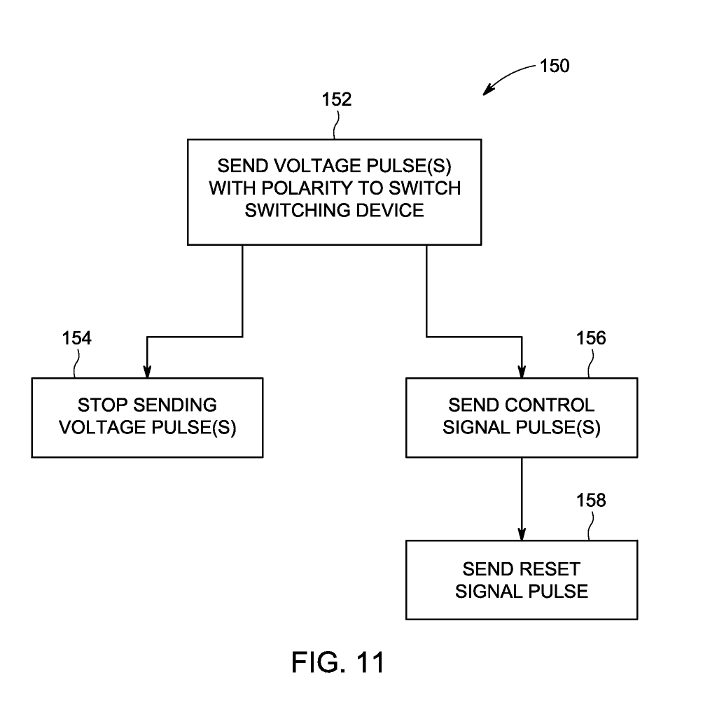

Various embodiments provide a method 150 as shown in FIG. 11 for controlling voltage switching, for example, to control switching of a plurality devices that are referenced to different voltages, which in some embodiments, are high voltages (e.g., 10 kV or higher). The method 150 includes sending one or more voltage pulses through the primary of one or more transformers as described herein. The voltage pulses have a polarity to turn on one of two switching devices in some embodiments. In a passive control arrangement as described herein, the switching device is turned off by stopping the sending of the voltage pulses. In an active control arrangement, the voltage pulses provide power signals to the switching devices from an on-board power supply. In this embodiment, one or more control signal pulses (e.g., odd or even number of pulses) may be sent to turn on or off the switching devices. Additionally, a reset signal pulse may be sent to reset the switching to a default operating mode, for example, a default operating mode of a flip-flop as described herein.

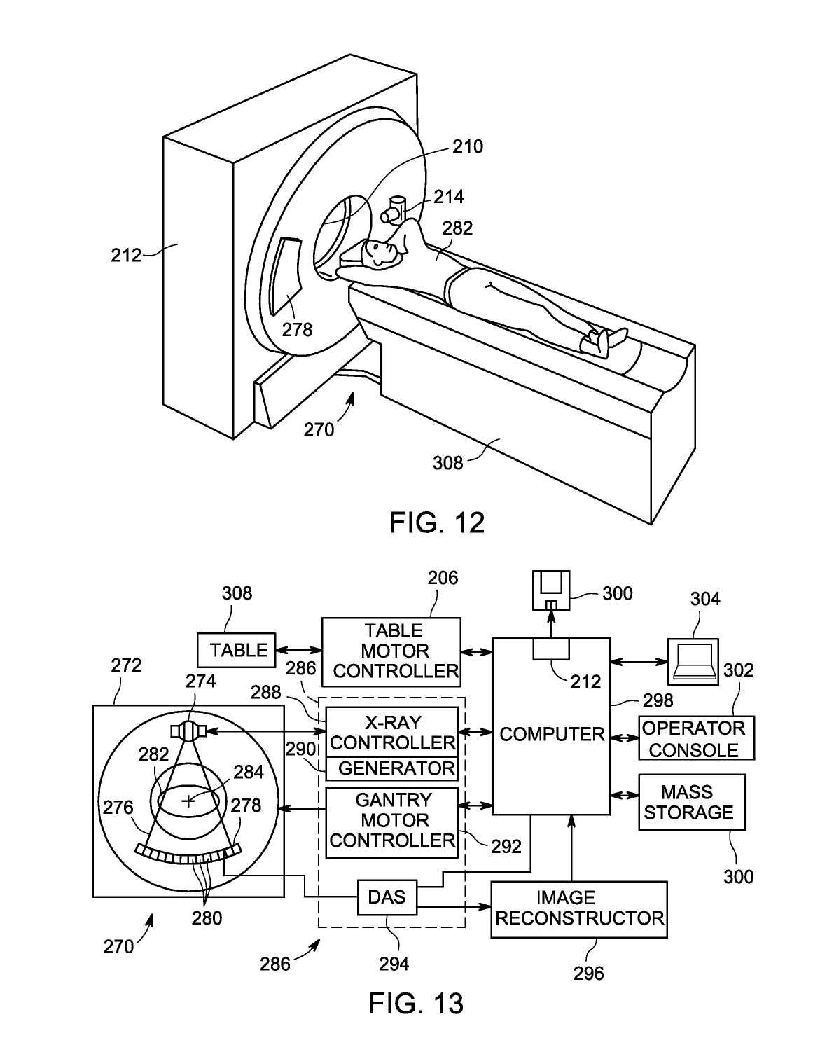

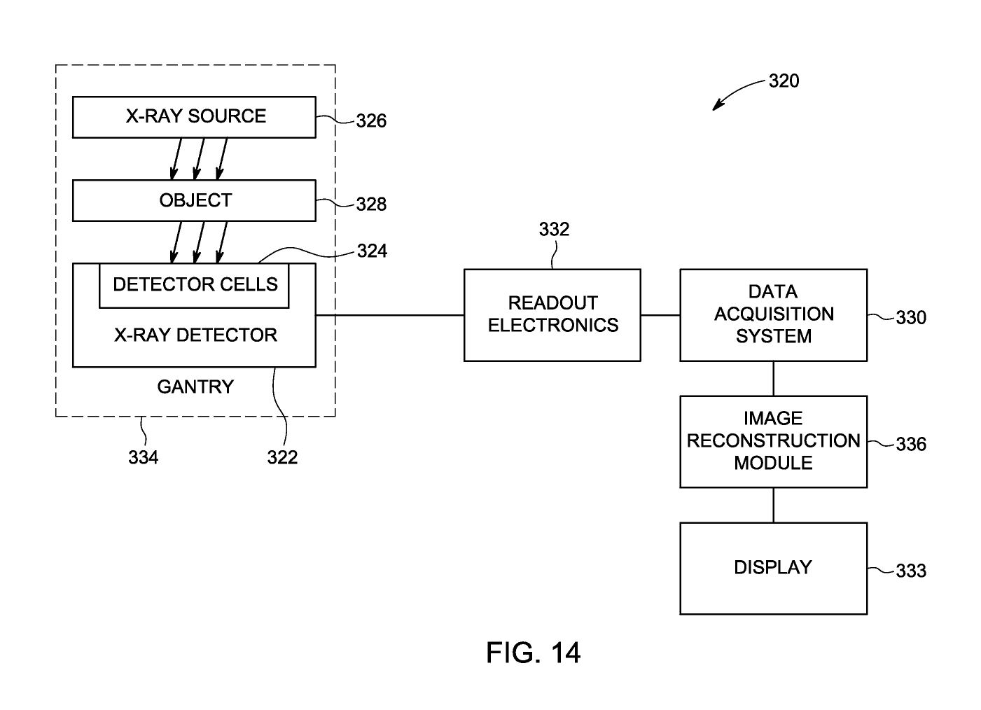

The various embodiments may be implemented in different systems using high-voltage sources. For example, the various embodiments may be implemented in connection with a CT imaging system as shown in FIGS. 12 and 13, or an x-ray imaging system as shown in FIG. 14, which may be a radiographic or x-ray tomosynthesis system.

In particular, FIG. 12 is a pictorial view of a CT imaging system 270. FIG. 13 is a block schematic diagram of the system 270 illustrated in FIG. 8. In the exemplary embodiment, the CT imaging system 270 is shown as including a gantry 272 representative of a “third generation” CT imaging system. The gantry 272 has an x-ray source 274 that projects a cone beam 276 of x-rays toward a detector array 278 on the opposite side of gantry 272.

The detector array 278 is formed by a plurality of detector rows (not shown) including a plurality of detector elements 280 that together sense the projected x-ray beams that pass through an object, such as a medical patient 282 or piece of baggage. Each detector element 280 produces an electrical signal that represents the intensity of an impinging x-ray radiation beam and hence the attenuation of the beam as it passes through object or patient 282. The imaging system 270 having a multislice detector 278 is capable of providing a plurality of images representative of a volume of object 282. Each image of the plurality of images corresponds to a separate “slice” of the volume. The “thickness” or aperture of the slice is dependent upon the height of the detector rows.

During a scan to acquire x-ray projection data, a rotating portion (not shown) within the gantry 272 and the components mounted thereon rotate about a center of rotation 284. FIG. 13 shows only a single row of detector elements 280 (i.e., a detector row). However, the multislice detector array 278 includes a plurality of parallel detector rows of detector elements 280 such that projection data corresponding to cone-beam geometry can be acquired simultaneously during a scan.

Rotation of the gantry 272 and the operation of radiation source 274 are governed by a control mechanism 286. The control mechanism 286 includes an x-ray controller 288 and generator 290 that provides power and timing signals to the x-ray source 274 (such as using the passive drive arrangement 30 or active drive arrangement 80) and a gantry motor controller 292 that controls the rotational speed and position of rotating portion of gantry 272. A data acquisition system (DAS) 294 in the control mechanism 286 samples analog data from detector elements 280 and converts the data to digital signals for subsequent processing. An image reconstructor 296 receives sampled and digitized measurement data from the DAS 294 and performs high-speed image reconstruction. The reconstructed image is applied as an input to a computer 298 that stores the image in a mass storage device 300. Although shown as a separate device, image reconstructor 296 may be special hardware located inside computer 298 or software executing within computer 298.

The computer 298 also receives commands and scanning parameters from an operator via a console 302 that has a keyboard and/or other user input device(s). An associated display system 304 allows the operator to observe the reconstructed image and other data from the computer 298. The operator supplied commands and parameters are used by the computer 298 to provide control signals and information to the DAS 294, x-ray controller 288, generator 290, and gantry motor controller 292. In addition, the computer 298 operates a table motor controller 306 that controls a motorized table 308 to position the patient 182 or object in the gantry 272. The table 308 moves portions of the patient 272 through a gantry opening 310.

In one embodiment, the computer 298 includes a device 312, for example, a CD-ROM drive, DVD-ROM drive, or a solid state hard drive for reading instructions and/or data from a computer-readable medium 314, such as a CD-ROM, or DVD. It should be understood that other types of suitable computer-readable memory are recognized to exist (e.g., CD-RW and flash memory, to name just two), and that this description is not intended to exclude any of these. In another embodiment, the computer 298 executes instructions stored in firmware (not shown). Generally, a processor in at least one of the DAS 294, reconstructor 296, and computer 298 shown in FIG. 13 is programmed to execute control commands to perform switching as described in more detail herein. The switching is not limited to practice in the CT system 270 and can be utilized in connection with many other types and variations of imaging systems. In one embodiment, the computer 298 is programmed to perform different functions to switch the switching devices described herein, accordingly, as used herein, the term computer is not limited to just those integrated circuits referred to in the art as computers, but broadly refers to computers, processors, microcontrollers, microcomputers, programmable logic controllers, application specific integrated circuits, and other programmable circuits.

FIG. 14 illustrates an x-ray imaging system 320 in which various embodiments may be implemented. The imaging system 320 generally includes an x-ray detector 322 having an array of detector cells 324 defining a scan area, and an x-ray source 326. An object 328, such as a patient or piece of luggage is positioned between the x-ray source 326 (the voltage switching of which may be controlled using the passive drive arrangement 30 or active drive arrangement 80) and the x-ray detector 322, which may be one or more detectors or detector modules. However, the imaging system 320 may also scan other objects, such as in an industrial inspection application. The imaging system 320 also includes a data acquisition system 330, which interacts with readout electronics 332. The readout electronics 332 may reside inside x-ray detector 322 or the data acquisition system 330.

In one embodiment, the x-ray detector(s) 322 may be flat-panel detector systems such as an amorphous silicon flat panel detector or other type of digital x-ray image detector, such as a direct conversion type detector, as is known to those skilled in the art. In another embodiment, the x-ray detector(s) 322 may include a scintillator having a screen that is positioned in front of the x-ray detector(s) 322.

It should be noted that the imaging system 320 may be implemented as a non-mobile or mobile imaging system. Moreover, the imaging system 320 may be provided in different configurations. For example, image data may be generated with the x-ray source 326 at discrete foci along a small arc above the object to generate the image information using computed tomosynthesis procedures and processes (or may be in a radiographic configuration). In other embodiments, the x-ray source 326 and the x-ray detector 322 are both mounted at opposite ends of a gantry 334, which may be a C-arm that rotates about the object 328. The rotatable C-arm is a support structure that allows rotating the x-ray source 326 and the x-ray detector 322 around the object 328 along a substantially circular arc, to acquire a plurality of projection images of the object 328 at different angles (e.g., different views or projections) that are typically less than 360 degrees, but may comprise a complete rotation in some instances.

In operation, the object 328 is positioned in the imaging system 320 for performing an imaging scan. For example, the x-ray source 326 may be positioned above, below or around the object 328. For example, the x-ray source 326 (and the x-ray detector(s) 322) may be moved between different positions around the object 328 using the gantry 334. X-rays are transmitted from the x-ray source 326 through the object 328 to the x-ray detector(s) 322, which detect x-rays impinging thereon.

The readout electronics 332 may include a reference and regulation board (RRB) or other data collection unit. The RRB may accommodate and connect data modules to transfer data (e.g., a plurality of views or projections) from the x-ray detector(s) 322 to the data acquisition system 330. Thus, the readout electronics 332 transmit the data from the x-ray detector(s) 322 to the data acquisition system 330. The data acquisition system 330 forms an image from the data and may store, display (on the display 333), and/or transmit the image. For example, the various embodiments may include an image reconstruction module 336, which may be implemented in hardware, software, or a combination thereof, that allows the data acquisition system to reconstruct images using x-ray data (e.g., radiographic or tomosynthesis data) acquired from the x-ray detector(s) 322 and as described in more detail herein.

Different examples and aspects of the apparatus and methods are disclosed herein that include a variety of components, features, and functionality. It should be understood that the various examples and aspects of the apparatus and methods disclosed herein may include any of the components, features, and functionality of any of the other examples and aspects of the apparatus and methods disclosed herein in any combination, and all of such possibilities are intended to be within the spirit and scope of the present disclosure.

It should be noted that the particular arrangement of components (e.g., the number, types, placement, or the like) of the illustrated embodiments may be modified in various alternate embodiments. In various embodiments, different numbers of a given module, system, or unit may be employed, a different type or types of a given module, system, or unit may be employed, a number of modules, systems, or units (or aspects thereof) may be combined, a given module, system, or unit may be divided into plural modules (or sub-modules), systems (or sub-systems) or units (or sub-units), a given module, system, or unit may be added, or a given module, system or unit may be omitted.

It should be noted that the various embodiments may be implemented in hardware, software or a combination thereof. The various embodiments and/or components, for example, the modules, systems, or components and controllers therein, also may be implemented as part of one or more computers or processors. The computer or processor may include a computing device, an input device, a display unit, and an interface. The computer or processor may include a microprocessor. The microprocessor may be connected to a communication bus. The computer or processor may also include a memory. The memory may include Random Access Memory (RAM) and Read Only Memory (ROM). The computer or processor further may include a storage device, which may be a hard disk drive or a removable storage drive such as a solid state drive, optical drive, and the like. The storage device may also be other similar means for loading computer programs or other instructions into the computer or processor.

As used herein, the term “computer,” “controller,” “system,” and “module” may each include any processor-based or microprocessor-based system including systems using microcontrollers, reduced instruction set computers (RISC), application specific integrated circuits (ASICs), logic circuits, GPUs, FPGAs, and any other circuit or processor capable of executing the functions described herein. The above examples are exemplary only, and are thus not intended to limit in any way the definition and/or meaning of the term “module,” “system,” or “computer.”

The computer, module, system, or processor executes a set of instructions that are stored in one or more storage elements, in order to process input data. The storage elements may also store data or other information as desired or needed. The storage element may be in the form of an information source or a physical memory element within a processing machine.

The set of instructions may include various commands that instruct the computer, module, system, or processor as a processing machine to perform specific operations such as the methods and processes of the various embodiments described and/or illustrated herein. The set of instructions may be in the form of a software program. The software may be in various forms such as system software or application software and which may be embodied as a tangible and non-transitory computer readable medium. Further, the software may be in the form of a collection of separate programs, systems, or modules, a program module within a larger program or a portion of a program module. The software also may include modular programming in the form of object-oriented programming. The processing of input data by the processing machine may be in response to operator commands, or in response to results of previous processing, or in response to a request made by another processing machine.

As used herein, the terms “software” and “firmware” are interchangeable, and include any computer program stored in memory for execution by a computer, including RAM memory, ROM memory, EPROM memory, EEPROM memory, and non-volatile RAM (NVRAM) memory. The above memory types are exemplary only, and are thus not limiting as to the types of memory usable for storage of a computer program. The individual components of the various embodiments may be virtualized and hosted by a cloud type computational environment, for example to allow for dynamic allocation of computational power, without requiring the user concerning the location, configuration, and/or specific hardware of the computer system.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the various embodiments without departing from the scope thereof. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the various embodiments should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, paragraph (f), unless and until such claim limitations expressly use the phrase “means for” followed by a statement of function void of further structure.

This written description uses examples to disclose the various embodiments, and also to enable a person having ordinary skill in the art to practice the various embodiments, including making and using any devices or systems and performing any incorporated methods. The patentable scope of the various embodiments is defined by the claims, and may include other examples that occur to those skilled in the art. Such other examples are intended to be within the scope of the claims if the examples have structural elements that do not differ from the literal language of the claims, or the examples include equivalent structural elements with insubstantial differences from the literal languages of the claims.

What is claimed is:

1. A voltage switching system comprising:
one or more transformers having primary and secondary windings;
a plurality of switching devices, at least two of the switching devices configured to produce different voltage outputs from a voltage input generated at the transformer, the plurality of switches electrically referenced to one or more voltages; and
a drive arrangement connected to the plurality of switches and configured to receive one or more voltage control pulses through the primary and secondary windings of the transformer, the drive arrangement switching one or more of the plurality of switches based on the one or more voltage control pulses.

2. The voltage switching system of claim 1, wherein the drive arrangement comprises a capacitor connected with each of the plurality of switches, the capacitors causing one or more of the plurality of switches to turn on when in a charged state and causing one or more of the plurality of switches to turn off when in a discharged state.

3. The voltage switching system of claim 2, further comprising a pair of diodes connected to the capacitors and configured to allow current flow to different ones of the capacitors based on the polarity of the voltage control pulses.

4. The voltage switching system of claim 2, wherein the voltage control pulses comprise a pulse train and the drive arrangement is configured to maintain at least one of the capacitors in the charged state based on the pulse train.

5. The voltage switching system of claim 1, wherein the drive arrangement is configured to switch on different ones of the plurality of switches based on a polarity of the voltage control pulses.

6. The voltage switching system of claim 1, further comprising a plurality of drive arrangements connected to different secondary windings of the transformer and wherein the transformer comprises a single primary winding.

7. The voltage switching system of claim 1, wherein the drive arrangement comprises a flip-flop configured in a toggle mode and connected to each of the switching devices.

8. The voltage switching system of claim 7, wherein the voltage control pulses comprise a first pulse having a first amplitude and a second pulse having a second amplitude different than the first pulse, wherein the drive arrangement uses the first pulse to power the plurality of switches and the second pulse to control switching of the plurality of switches.

9. The voltage switching system of claim 8, wherein the voltage control signals comprise a third pulse having a third amplitude different than the first and second amplitudes, wherein the drive arrangement use the third pulse to reset the flip-flop.

10. The voltage switching system of claim 9, wherein the amplitude of the third pulse is higher than the amplitude of the second pulse and the amplitude of the second pulse is higher than the amplitude of the first pulse.

11. The voltage switching system of claim 1, where the voltage input defines a reference voltage of about 10 kV or greater.

12. The voltage switching system of claim 11, wherein the voltage control pulse comprise voltage signals that are less than about 20 volts.

13. The voltage switching system of claim 1, wherein the plurality of switches are connected in a common emitter configuration.

14. The voltage switching system of claim 1, wherein the voltage switching system is configured to operate in one of a CT system, an x-ray radiographic system, or an x-ray tomosynthesis system.

15. The voltage switching system of claim 1, further comprising a plurality of printed circuit boards (PCBs), at least two of the PCBs referenced to a different voltage and the drive arrangement controlling voltage switching to the plurality of PCBs.

16. The voltage switching arrangement of claim 1, wherein the drive arrangement comprises a plurality of gate drive circuits, and further comprising a plurality of transformers, each having a plurality of primary and secondary windings, wherein the primary windings are connected in series and wherein the secondary windings for each of the plurality of transformers is connected to a different gate drive circuit of the plurality of gate drive circuits.

17. The voltage switching arrangement of claim 1, wherein the drive arrangement comprises a plurality of gate drive circuits, and further comprising a plurality of transformers wherein the primary winding are connected in series, and each transformer having a single secondary winding, wherein the secondary windings for each of the plurality of transformers is connected to a different gate drive circuit of the plurality of gate drive circuits.

18. The voltage switching arrangement of claim 1, wherein the drive arrangement comprises a plurality of gate drive circuits, and the one or more transformers comprises a single primary winding and a plurality of secondary windings, wherein the secondary windings are each connected to a different gate drive circuit of the plurality of gate drive circuits.

19. The voltage switching arrangement of claim 1, wherein the drive arrangement comprises a single gate drive circuit connected to the secondary winding of the one or more transformers.

20. An x-ray system comprising:
an x-ray source including an x-ray tube configured to operate at a plurality of different voltages;
a plurality of switching devices, at least two of the switching devices configured to produce different voltage outputs from a voltage input generated at a transformer to control the switching of the x-ray tube at the plurality of different voltages; and
a drive arrangement connected to the plurality of switches and configured to receive one or more voltage control pulses through the primary windings of the transformer, the drive arrangement switching one or more of the plurality of switches based on the one or more voltage control pulses.

21. The x-ray system of claim 20, further comprising a plurality of printed circuit boards (PCBs), at least two of the PCBs referenced to at least two of the plurality of different voltages.

22. The x-ray system of claim 20, wherein the plurality of voltage are at voltage levels of 10 kV or greater.

23. The x-ray system of claim 20, wherein the plurality of switches comprise transistors and the drive arrangement comprises one of a passive gate drive or an active gate drive configured to generate a drive signals for a gate of the transistors, the passive gate drive including a capacitor connected with each of the plurality of switches, the capacitors causing one or more of the plurality of switches to turn on when in a charged state and causing one or more of the plurality of switches to turn off when in a discharged state, and a pair of diodes connected to the capacitors and configured to allow current flow to different ones of the capacitors based on the polarity of the voltage control pulses, the passive date drive configured to switch on different ones of the plurality of switches based on a polarity of the voltage control signal.

24. The x-ray system of claim 23, wherein the active gate drive comprises a flip-flop configured in a toggle mode connected to each of the switching devices, wherein the voltage control pulses comprise a first pulse having a first amplitude and a second pulse having a second amplitude different than the first pulse, the active gate drive configured to use the first pulse to power the plurality of switches and the second pulse to control switching of the plurality of switches.

25. The x-ray system of claim 20, wherein the voltage control pulses comprise a third pulse having a third amplitude different than the first and second amplitudes, the active gate drive configured to use the third pulse to reset the flip-flop and wherein the amplitude of the third pulse is higher than the amplitude of the second pulse and the amplitude of the second pulse is higher than the amplitude of the first pulse.

26. A method for controlling voltage switching, the method comprising:
configuring a plurality of switching devices electrically referenced to a plurality of voltages to produce different voltage outputs from a voltage input generated at a transformer, and
configuring a drive arrangement connected to the plurality of switches and configured to receive one or more voltage control pulses through the primary windings of the transformer, the drive arrangement switching one or more of the plurality of switches based on the one or more voltage control pulses.
